(19) United States
(12) Patent Application Publication
(10) Pub. No.: US 2010/0022039 A1
(43) Pub. Date: Jan. 28, 2010

(54) METHOD OF MAKING LIGHT EMITTING DIODES

(75) Inventor: CHIA-SHOU CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXCONN TECHNOLOGY CO., LTD., Tu-Cheng (TW)

(21) Appl. No.: 12/426,281

(22) Filed: Apr. 20, 2009

(30) Foreign Application Priority Data
Jul. 28, 2008 (CN) 200810303127.5

(51) Int. Cl. H01L 21/56; H01L 21/78

(52) U.S. Cl. 438/28; 438/33; 257/E21.502; 257/E21.599

(57) ABSTRACT

A method of making LEDs simultaneously includes steps of : a) providing a wafer having LED dies on a substrate; b) forming a passivation layer on the LED dies; c) forming an electrode layer on the passivation layer and the LED dies; d) assembling a conducting board on the electrode layer; e) removing the substrate to expose a light emitting surface of each LED die; f) forming a terminal on the light emitting surface; g) forming a channel at a lateral side of each LED die; h) assembling a cover onto the LED dies; i) wire bonding and encapsulating the LED dies to the LEDs connected with each other; and j) cutting through the interconnected LEDs to form the LEDs separated from each other.

### BACKGROUND

1. Technical Field

The disclosure generally relates to a method of making light emitting diodes, and particularly to a method of making a plurality of light emitting diodes simultaneously.

2. Description of Related Art

In recent years, light emitting diodes (LEDs) have been widely used in illumination. Typically, an LED device includes a plurality of LEDs. Each LED includes an LED chip arranged in a reflector cup and electrically connected to an external circuit. In addition, the LED chip is packaged to protect it from environmental harm and mechanical damage. However, generally, to form the plurality of LEDs, each LED chip is individually mounted into the reflector cup and then connected to a circuit board through wire bonding, and finally transparent material is filled into the reflector cup to encapsulate the LED chip to form an LED. In other words, the LEDs are formed separately at a time, which is costly, time-consuming and may require substantial amounts of manual labor and/or specialized equipment.

For the foregoing reasons, therefore, there is a need in the art for a method for making LEDs which overcomes the limitations described.

### BRIEF DESCRIPTION OF THE DRAWINGS

FIG. 1 is a flow chart of a method of making a plurality of light emitting diodes simultaneously according to an exemplary embodiment.

FIG. 2 is a cross sectional view showing a plurality of LED dies formed on a substrate.

FIG. 3 is a cross sectional view showing a passivation layer formed on the substrate and the LED dies of FIG. 2.

FIG. 4 is a cross sectional view showing an electrode layer formed on the passivation layer and the LED dies of FIG. 3, in which the electrode layer has a first bonding layer thereon.

FIG. 5 is a cross sectional view showing assembly of a conducting board onto the bonding layer of the electrode layer of FIG. 4.

FIG. 6 is a cross sectional view showing the substrate being removed from the LED dies and the passivation layer of FIG. 5.

FIG. 7 is a cross sectional view showing a plurality of terminals formed on the LED dies of FIG. 6.

FIG. 8 is a cross sectional view showing a part of the passivation layer being removed from the LED dies and the electrode layer of FIG. 7.

FIG. 9 is a cross sectional view showing a plurality of channels filled with insulating material being formed in the electrode layer and the conducting layer of FIG. 8.

FIG. 10 is a cross sectional view of a cover.

FIG. 11 shows the cover being assembled onto the LED dies and electrode layer of FIG. 9.

FIG. 12 is a cross sectional view showing the LED dies of FIG. 11 being encapsulated to form a plurality of LEDs integrally connected together.

FIG. 13 is a diagrammatical top view showing a cutting template over the LEDs of FIG. 12 for guiding a cutting through the plurality of LEDs to separate the LEDs into individual ones.

FIG. 14 is a cross sectional view showing one of the separated LEDs formed according to the exemplary method of FIGS. 2-13.

FIG. 15 is similar to FIG. 12, but shows an alternative cover assembled onto the LED dies and the electrode layer.

### DETAILED DESCRIPTION

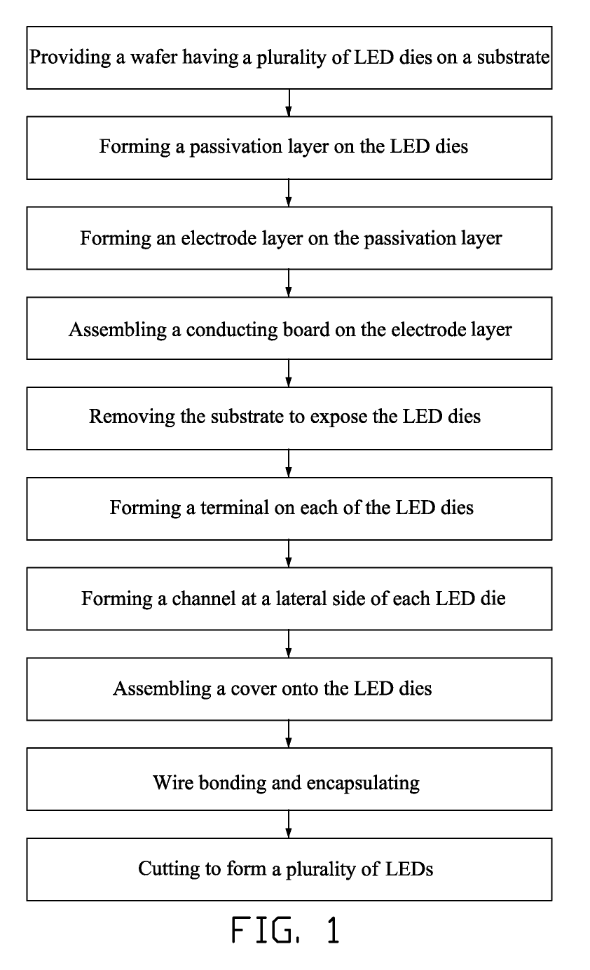

Referring to FIG. 1, a flow chart of a method for making a plurality of light emitting diodes (LEDs) 20 simultaneously according to an exemplary embodiment is shown. The method mainly includes steps of: a) forming a plurality of LED dies on a substrate; b) forming a passivation layer on the LED dies; c) forming an electrode layer on the passivation layer; d) assembling a conducting board on the electrode layer; e) removing the substrate to expose the LED dies; f) forming a terminal on each of the LED dies; g) forming a channel at a lateral side of each of the LED dies; h) assembling a cover onto the LED dies; i) wire bonding and encapsulating the LED dies to form a plurality of interconnected LEDs; and j) cutting through the interconnected LEDs to obtain a plurality of individual LEDs. Details are given below.

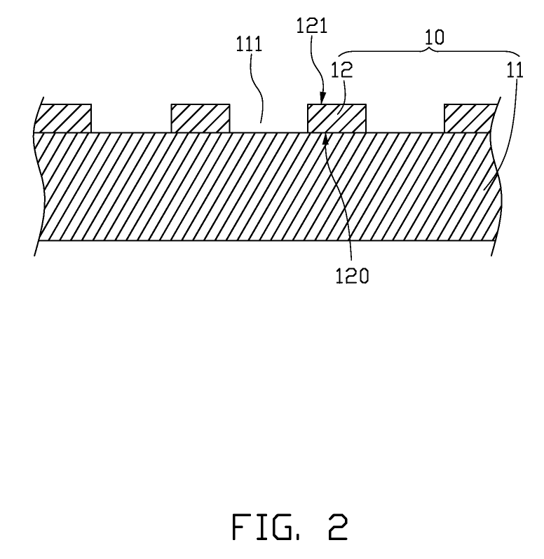

Referring to FIG. 2, firstly, a wafer 10 is provided. The wafer 10 is formed by growing an epitaxial layer on a substrate 11 which has been washed by weak acid solution to remove foreign particles thereof beforehand. The substrate 11 is sapphire, and the epitaxial layer is gallium arsenide, gallium arsenide phosphide or aluminum gallium arsenide. The epitaxial layer forms a p-n junction structure, including an N-doped region and a P-doped region at upper and lower sides thereof, respectively. Then the epitaxial layer is cut to form a plurality of LED dies 12 on the substrate 11. The LED dies 12 are evenly distributed on the substrate 11 with a gap 111 defined between two neighboring LED dies 12. Each LED die 12 includes a p-n junction, and has a P-pole and an N-pole at top and bottom portions thereof. Each LED die 12 has an emitting surface 120 formed at a bottom side thereof contacting with the substrate 11 directly.

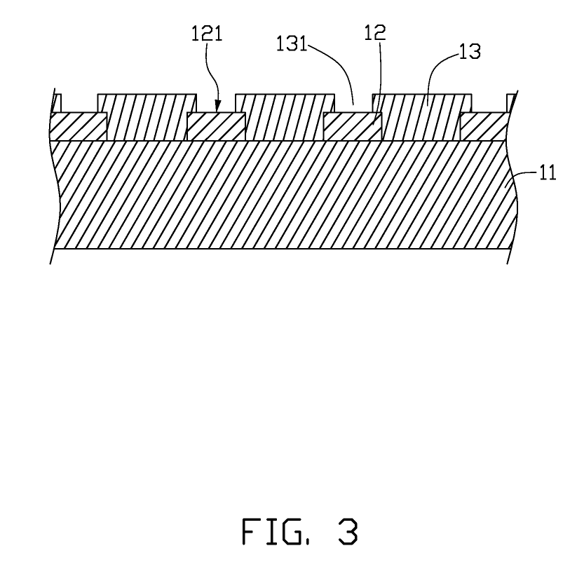

Referring to FIG. 3, a passivation layer 13 is then coated onto the LED dies 12 and the substrate 11 through spin coating. The passivation layer 13 is photo resist, which is a light-sensitive material and used to form an electrode pattern. A bottom of the passivation layer 13 extends into and fills the gaps 111 between the LED dies 12. A micro hole 131 is defined in the passivation layer 13 over each of the LED dies 12 through optical lithography. The micro holes 131 each have a horizontal cross section with a size smaller than that of a horizontal cross section of each of the LED dies 12, and thus lateral sides of a top surface 121 of each LED die 12 are covered by the passivation layer 13, and only a central portion of the top surface 121 of the LED 20 is exposed to an outside.

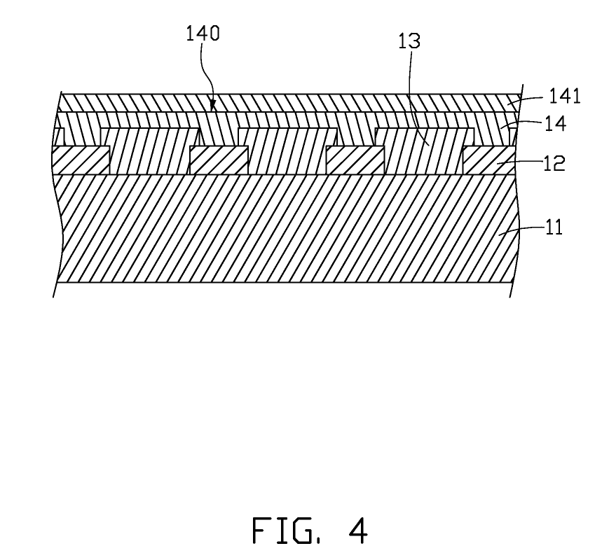

Referring to FIG. 4, an electrode layer 14 is then formed on the passivation layer 13 and the LED dies 12 through electroplating or sputtering deposition. The electrode layer 14 fills the micro holes 131 of the passivation layer 13 and forms a planar top surface 140. In other words, the electrode layer 14 contacts central portions of the top surfaces 121 of the LED dies 12 directly. Therefore, each LED die 12 has one pole, i.e., the P-pole connected to the electrode layer 14 directly and electrically. A first bonding layer 141 of the electrode layer 14 is integrally formed on the top surface 140 of the electrode layer 14. The first bonding layer 141 is a eutectic alloy, such as Al—Si alloy or Cu—Si alloy.

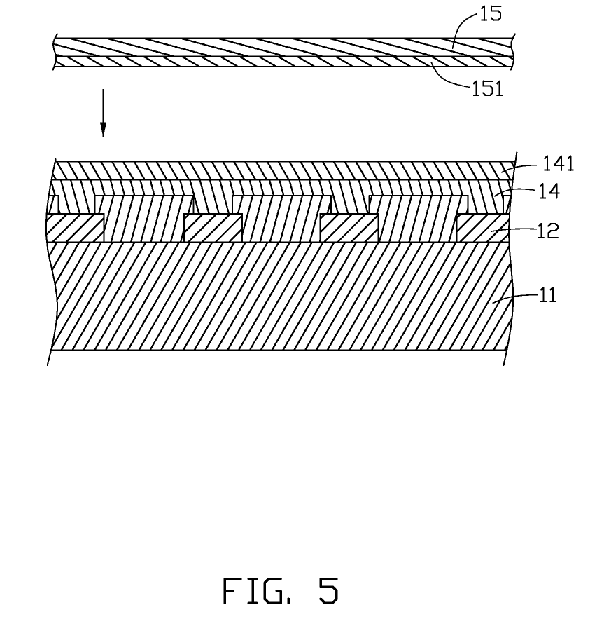

Referring to FIG. 5, a conducting board 15 is then provided with a second bonding layer 151 formed thereon. Similar to the first bonding layer 141, the second bonding layer 151 is made of a eutectic alloy, and is integrally coated on the conducting board 15. The conducting board 15 is then assembled on to the electrode layer 14 with the first bonding layer 141 and the second bonding layer 151 connected together. The first and second bonding layers 141, 151 are connected to be integral through wafer bonding, and thus the substrate 11, the LED dies 12, the passivation layer 13, the electrode layer 14 and the conducting board 15 are integral.

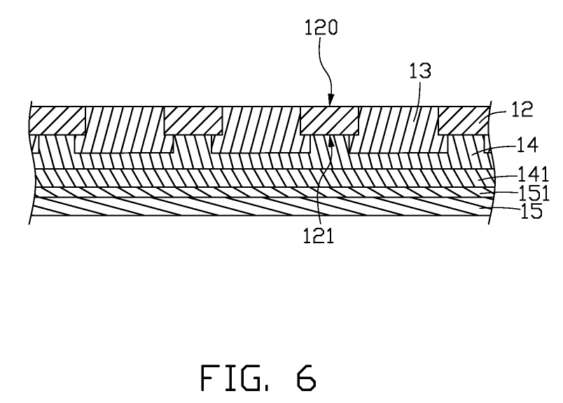

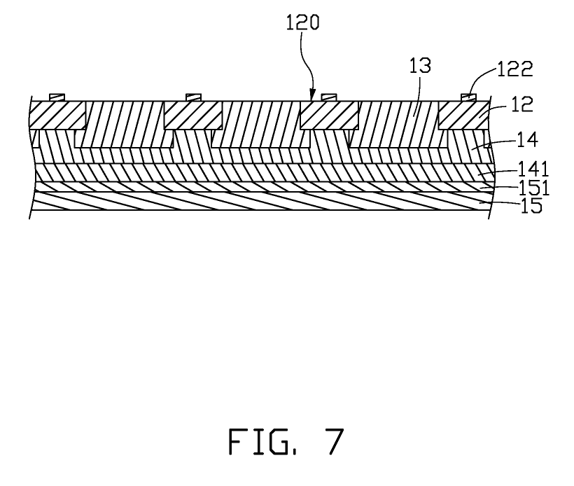

Referring to FIG. 6, the substrate 11 is then removed through lift-off, such as laser lift-off. The LED dies 12 with the passivation layer 13, the electrode layer 14 and the conducting board 15 are then inverted. In such a situation, the conducting board 15 is located at the bottom to support the electrode layer 14, the passivation layer 13, and the LED dies 12 thereon. The LED dies 12 are located at the top with the entire emitting surfaces 120 thereof exposed to the outside. Referring to FIG. 7, a terminal 122 is then formed on a central portion of the emitting surface 120 of each of the LED dies 12; thus, the other pole of each LED die 12, i.e., the N-pole is connected to the terminal 122 electrically and directly.

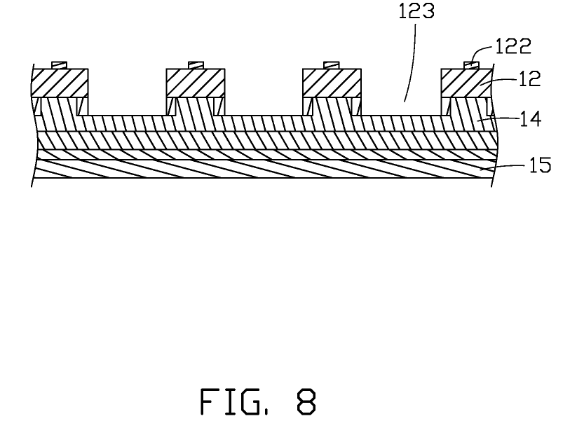

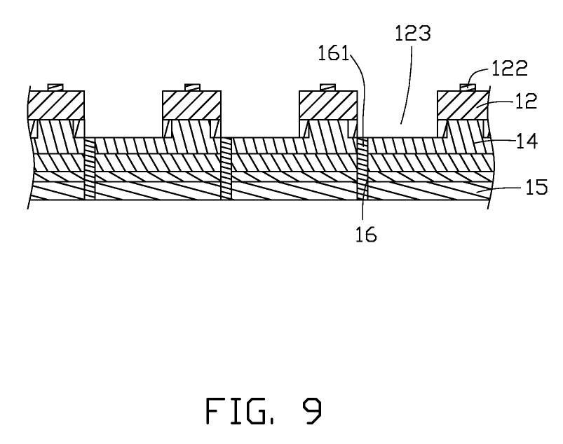

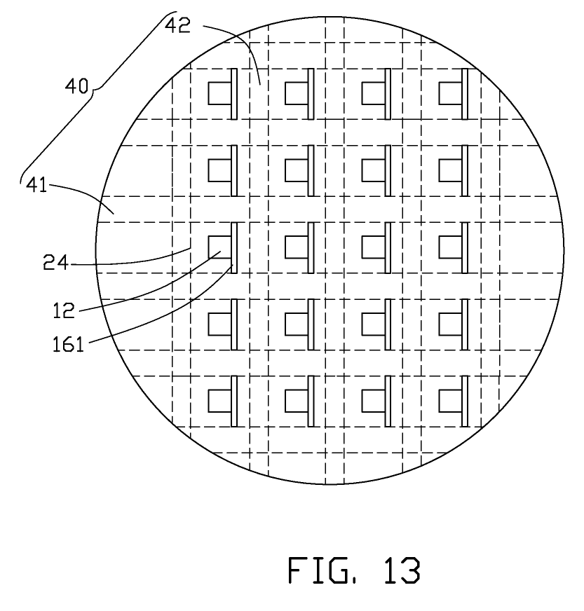

Referring to FIG. 8, after the terminals 122 are formed, a part of the passivation layer 13 between the LED dies 12 is removed, and thus a space 123 is defined between adjacent LED dies 12 and over the electrode layer 14. A portion of the electrode layer 14 between the LED dies 12 is exposed to the outside. Then, referring to FIGS. 9 and 13, a channel 16 is defined adjacent to each LED die 12. In this embodiment, each channel 16 is located at a right side of the corresponding LED die 12, and has a length larger than a width of the corresponding LED die 12, as best seen from FIG. 13. Two opposite ends of each channel 16 extend beyond front and rear sides of the corresponding LED die 12. The channels 16 extend through the electrode layer 14 and the conducting board 15 vertically. An electrically insulating material 161 is filled in each of the channels 16.

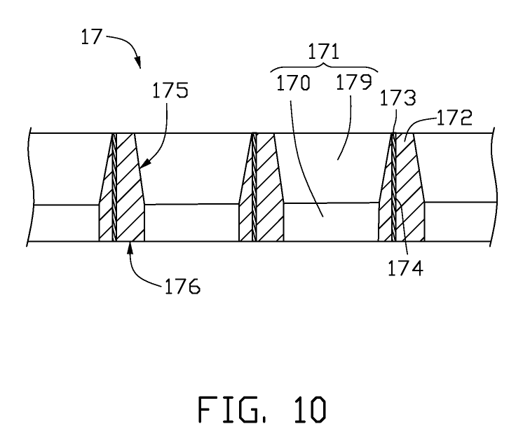

Referring to FIG. 10, an insulating cover 17 is then provided with a plurality of recesses 171 defined therein for receiving the LED dies 12. The amount and position of the recesses 171 are decided according to the amount and position of the LED dies 12. The recesses 171 extend through the cover 17 vertically. Each recess 171 includes a lower portion 170 and an upper portion 179. The lower portion 170 is substantially column-shaped. A size of a horizontal cross section of the lower portion 170 of the recess 171 is larger than a sum of sizes of horizontal cross sections of the LED die 12 and the corresponding channel 16, and a depth of the lower portion 170 is slightly smaller than a height between the electrode layer 14 and the emitting surface 120 of the LED die 12. The upper portion 179 is conversely truncated conical, and expands upwardly and gradually from the lower portion 170. The cover 17 thus forms a reflecting surface 175 surrounding each recess 171. A layer of material with a high reflectivity, such as mercury, is coated on the reflecting surface 175 for increasing the reflectivity of the cover 17. A through hole 174 is defined in the cover 17 at a right side of each recess 171. An electric pole 173 is received in each of the through holes 174.

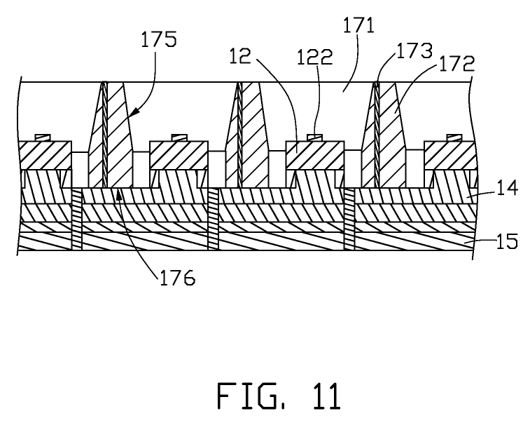

As shown in FIG. 11, when the cover 17 is assembled on the LED dies 12, a bottom side 176 of the cover 17 attaches to the portion of the electrode layer 14 exposed to the outside. Each LED die 12 is received in a corresponding recess 171. A solid part 172 of the cover 17 between adjacent LED dies 12 is spaced from the LED dies 12, and is located at a right side of the channel 16, whereby the electric pole 173 in the cover 17 is located at a right side of the corresponding channel 16.

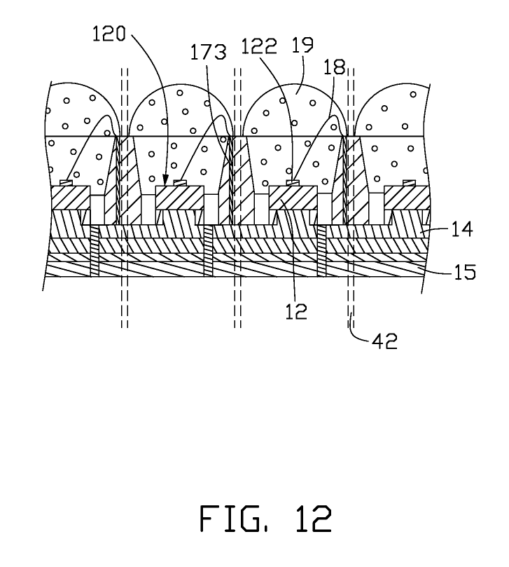

Referring to FIG. 12, after the cover 17 is assembled to the LED dies 12, the terminal 122 of each of the LED dies 12 is electrically connected to the electric pole 173 at the right side thereof through wire bonding, in which a gold wire 18 interconnects a top end of the electric pole 173 and the LED die 12. Thus the other pole, i.e., the N-pole of the LED die 12 is connected to the electrode layer 14 at a right side of the channel 16 through the wire 18 and the electric pole 173. Then, light penetrable material, particularly, transparent material, such as glass, resin, acryl or silica gel is brought to fill the recesses 171 of the cover 17 to form a packaging layer 19 to encapsulate each of the LED dies 12, whereby the plurality of LEDs 20 are formed which are interconnected together.

Finally, the interconnected LEDs 20 are separated from each other to form the LEDs 20 in individual forms via a cutting operation through the plurality of LEDs 20. FIGS. 12 and 13 show a cutting template 40 for cutting the interconnected LEDs 20 to form the plurality of separated LEDs 20. The cutting template 40 includes a plurality of transverse paths 41 and a plurality of lengthways paths 42 intersecting the transverse paths 41. The transverse paths 41 are parallel to each other, and are evenly spaced from each other. A distance between close edges of two neighboring transverse paths 41 is equal to the length of the channel 16. Thus the two opposite ends of each channel 16 respectively align with the closed edges of the two neighboring transverse paths 41. The lengthways paths 42 are parallel to and evenly spaced from each other. A distance between two neighboring lengthways paths 42 is substantially equal to that between two neighboring electric poles 173. Each lengthways path 42 is adjacent to one electric pole 173 and is located at a right side of the electric pole 173. Thus two neighboring lengthways paths 42 and two neighboring transverse paths 41 cooperatively define a rectangular loop 24 surrounding one LED 20.

When a cutting tool cuts through the electrode layer 14 and the conducting board 15 along the lengthwise paths 42 and the traverse paths 41 of the cutting template 40, each LED 20 within the rectangular path 24 is separated from the other LEDs 20 to form an individual LED 20. In the present method, as the wire bonding process and the encapsulation process of the plurality of LED dies 12 can be done simultaneously, the plurality of LEDs 20 can be formed at the same time; thus, a production efficiency of the LEDs 20 is improved, and correspondingly a cost for producing the LEDs 20 is reduced.

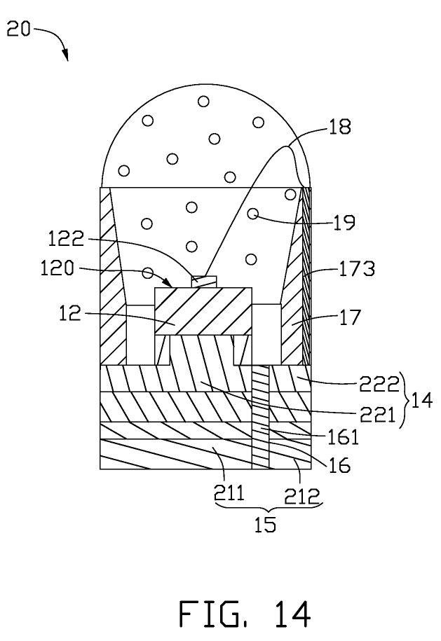

FIG. 14 shows one LED 20 formed by the present method that has one LED die 12 with the corresponding electrode layer 14 and the corresponding conducting board 15 under the LED die 12, and the corresponding packaging layer 19 encapsulating the LED die 12 to protect the LED die 12 from environmental harm and mechanical damage. The corresponding electrode layer 14 is divided into two portions by the channel 16, i.e., a left portion 221 and a right portion 222. Similarly, the corresponding conducting board 15 is divided into two portions by the channel 16, i.e., a left portion 211 and a right portion 212. The left portion 221 of the electrode layer 14 and the left portion 211 of the conducting board 15 are insulated from the right portion 222 of the electrode layer 14 and the right portion 212 of the conducting board 15 by the insulating material 161 in the channel 16. The left portions 221, 211 of the electrode layer 14 and the conducting board 15 are connected to the one pole, i.e., the P-pole of the LED die 12 electrically and directly, and thus acts as a first electrode of the LED 20. The right portions 222, 212 of the electrode layer 14 and the conducting board 15 are connected to the terminal 122 formed on the emitting surface 120 of the LED die 12 and the other one pole, i.e. the N-pole of the LED die 12, through the electric pole 173 and the gold wire 18. Thus, the right portions 222, 212 act as a second electrode of the LED 20. When the LED 20 is in use, the first and second electrodes of the LED 20 are connected to a power source, and thus electric current is supplied to the LED die 12 to cause the LED 20 to emit light.

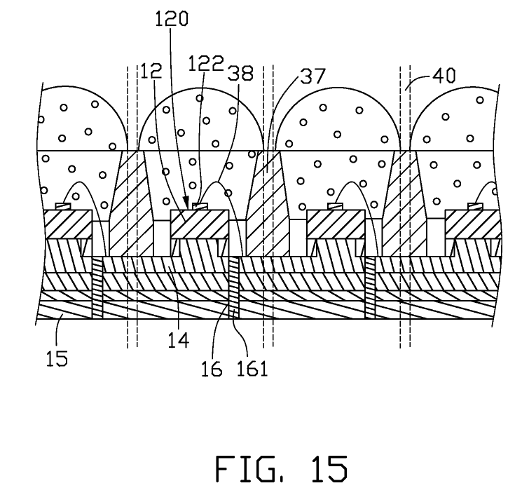

FIG. 15 shows an alternative cover 37 assembled onto the LED dies 12 after the terminals 122 are formed on the emitting surfaces 120 of the LED dies 12. Comparing this cover 37 with the previous cover 17, the through holes 174 and the electric poles 173 received in the through holes 174 of the cover 17 are omitted. The terminal 122 of each LED die 12 is connected to the electrode layer 14 at a right side of the channel 16 through a wire 38. After being cut along the transverse paths 41 and the lengthwise paths 42 of the cutting template 40 to form the individual LEDs, the terminal 122 of each LED die 12 is connected to the electrode layer 14 and the conducting board 15 at a position between the channel 16 and the cover 37 through the wire 38 to form the second electrode of the each LED.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method of making a plurality of light emitting diodes (LEDs) simultaneously, comprising steps of:
providing a wafer which comprises a plurality of LED dies on a substrate;
forming a passivation layer on the LED dies;
forming an electrode layer on the passivation layer contacting the LED dies;
providing a conducting board and assembling the conducting board on the electrode layer;
removing the substrate to expose a light emitting surface of each of the LED dies;
forming a terminal on the light emitting surface of each of the LED dies;
forming a channel at a lateral side of each of the LED dies;
providing a cover and assembling the cover onto the LED dies;
electrically connecting the terminals of the LED dies to the electrode layer and encapsulating the LED dies thereby to obtain the plurality of LEDs interconnected together; and
cutting the interconnected LEDs to form the plurality of LEDs separated from each other, each individual LED including a corresponding part of the electrode layer and a corresponding part of the conducting board, each of the corresponding parts of the electrode layer and conducting board being divided into two portions insulated from each other by a corresponding channel in the each individual LED.

2. The method of claim 1, wherein the passivation layer is photo resist, and is coated on the LED dies through spin coating, a micro hole being defined in the passivation layer over each of the LED dies through optical lithography, the electrode layer extending in and filling the micro holes of the passivation layer to contact the LED dies directly.

3. The method of claim 1, wherein a first bonding layer is coated on the electrode layer, and a second bonding layer is coated on the conducting board, the electrode layer being assembled onto the conducting board through connection of the first and second bonding layers.

4. The method of claim 3, wherein the first and second bonding layers each are eutectic alloy, and are connected to each other through wafer bonding.

5. The method of claim 1, wherein the channel is filled with an electrically insulating material.

6. The method of claim 1, wherein a length of the channel is larger than a width of the LED die, and two close edges of two neighboring cutting paths of a cutting template for facilitating and guiding the cutting the interconnected LEDs into the separated LEDs are aligned with opposite ends of the channel.

7. The method of claim 1, wherein the cover defines a plurality of recesses receiving the plurality of LED dies therein, respectively, and a solid part of the cover between each of the LED dies and a neighboring die is located at an outer lateral side of the channel, the channel being located between the solid part of the cover and each of the LED dies.

8. The method of claim 7, wherein an electric pole is formed in the solid part of the cover, one end of the electric pole being connected to the electrode layer directly, and another end of the electric pole being connected to the terminal of each of the LED dies through wire bonding.

9. The method of claim 7, wherein the terminal of each of the LED dies is connected to the electrode layer between the solid part of the cover and the channel through wire bonding.

10. The method of claim 1, wherein the substrate is removed through laser lift-off.

11. A method for manufacturing a plurality of LEDs at the same time, comprising:
providing a substrate and a plurality of LED dies on the substrate, each LED die having a top surface and bottom surface connecting with the substrate;
providing a passivation layer on the LED dies and the substrate wherein a central portion of the top surface of each LED die is exposed and not covered by the passivation layer;
providing an electrode layer on the passivation layer and the central portion of the top surface of each LED die, in which a first bonding layer is provided on the electrode layer;
securing a conducting board onto the electrode layer in which the conducting board has a second bonding layer integral with the first bonding layer;
removing the substrate from the LED dies and the passivation layer to expose the bottom surfaces of the LED dies;
removing the passivation layer from the LEDs and the electrode layer to expose a part of the electrode layer between every two neighboring LEDs;
inserting an electrically insulating material into the electrode layer and the conductive board at a first position near each LED die;
electrically connecting a corresponding bottom surface of each LED die with the electrode layer at a second position distant from each LED die so that the first position is between each LED die and the second position;
encapsulating each LED die to form the plurality of LEDs interconnecting with each other; and
cutting through the interconnected LEDs to obtain the plurality of LEDs separated from each other.

12. The method of claim 11, wherein the first and second bonding layers each are made of a eutectic alloy.

13. The method of claim 11, wherein the first and second bonding layers are integrated together by wafer bonding.

14. The method of claim 11, wherein at the step of electrically connecting a corresponding bottom surface of each LED die with the electrode layer, a conductive wire is used to directly connect the corresponding bottom surface of each LED die and the electrode layer.

15. The method of claim 14, wherein before the step of electrically connecting a corresponding bottom surface of each LED die with the electrode layer, a cover is mounted on the electrode layer, the cover defining a plurality of recesses each surrounding a corresponding LED die.

16. The method of claim 15, wherein the step of encapsulating each LED die includes filling light penetrable material into the recesses of the cover.

17. The method of claim 16, wherein each LED die emits light through the corresponding bottom surface thereof.

18. The method of claim 11, wherein before the step of electrically connecting a corresponding bottom surface of each LED die with the electrode layer, a cover is mounted on the electrode layer, the cover defining a plurality of recesses each surrounding a corresponding LED die, the cover having a plurality of electrodes therein, each electrode electrically connecting with the electrode layer at the second position and the corresponding bottom surface of each LED die being electrically connected to the electrode layer at the second position via a conductive wire interconnecting the corresponding bottom surface of each LED die and a corresponding electrode.

19. The method of claim 18, wherein the step of encapsulating each LED die includes filling light penetrable material into the recesses of the cover.

20. The method of claim 19, wherein each LED die emits light through the corresponding bottom surface thereof.
